(19) United States
(12) Patent Application Publication
(10) Pub. No.: US 2007/0076350 A1
(43) Pub. Date: Apr. 5, 2007

(54) Capacitor and electronic apparatus thereof

(76) Inventors: Masashi Watanabe, Ome-shi (JP); Toshiki Ooka, Hamura-shi (JP); Takahiro Sakaguchi, Ome-shi (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/529,666

(22) Filed: Sep. 27, 2006

(30) Foreign Application Priority Data
Sep. 30, 2005 (JP) 2005-285736

(51) Int. Cl. H01G 9/10; H05K 5/03; H01G 4/228

(52) U.S. Cl. 361/520

(57) ABSTRACT

According to one embodiment, a capacitor includes a first anode terminal exposed from an end portion of a first inner electrode coupled to one side of a dielectric in a predetermined direction, a second anode terminal exposed from the other end portion of the first electrode in the predetermined direction, a first cathode terminal exposed from a predetermined portion of a second inner electrode that is connected to the other side of the dielectric and provided independently of the first electrode, to insides of the exposed portions of the first and second anode terminals, in the predetermined direction, and a second cathode terminal exposed from a part of the predetermined portion of the second electrode which is close to the second anode terminal, to the insides of the exposed portions of the first and second anode terminals, in the predetermined direction, at a predetermined interval from the first cathode terminal.

### CROSS-REFERENCE TO RELATED APPLICATIONS

This application is based upon and claims the benefit of priority from Japanese Patent Application No. 2005-285736, filed Sep. 30, 2005, the entire contents of which are incorporated herein by reference.

### BACKGROUND

1. Field

One embodiment of the invention relates to a capacitor for use in a high-frequency electronic circuit and an electronic apparatus thereof.

2. Description of the Related Art

A capacitor having an electrode attached to a dielectric plate has been utilized in an electronic circuit as disclosed in, for example, Jpn. Pat. Appln. KOKAI Publication No. 2000-299259. Such a capacitor is provided, for example, between power supply lines of the electronic apparatus and thereby has an effect of removing noise between the power supply lines.

The capacitor has an electrode attached to a region occupying most parts of a flat plate portion of the dielectric plate and the electrode is exposed to the outside. In other words, when the capacitor is mounted on a circuit board, most parts of a bottom surface of the capacitor are covered with the exposed portion of the electrode. In mounting such a capacitor on the circuit board, a through hole or another wiring pattern cannot be formed on the circuit board located below the electrode.

Recently, an electronic apparatus typified by, for example, a personal computer, as operated with what is called a high frequency has been developed. When the capacitor is provided between the power supply lines of the apparatus, a frequency characteristic of an impedance of the capacitor in a high-frequency band is deteriorated as compared with that in a low-frequency band, due to an influence from inductance of a terminal portion of the capacitor.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a perspective view showing outer appearance of a conventional capacitor and a conventional circuit board;

FIG. 2 is a cross-sectional view showing the conventional capacitor and the conventional circuit board as seen along a line A-A′ of FIG. 1;

FIG. 3 is a perspective view showing an electrode exposure surface of the conventional capacitor;

FIG. 4 is a perspective view showing an outer appearance of a capacitor and an outer appearance of a circuit board according to a first embodiment of the present invention;

FIG. 5 is a cross-sectional view showing the capacitor and the circuit board according to the first embodiment of the present invention as seen along a line B-B′ of FIG. 4;

FIG. 6 is a perspective view showing an electrode exposure surface of the capacitor according to the first embodiment of the present invention;

FIG. 7 is a perspective view showing an outer appearance of a notebook-type PC containing a circuit board on which a capacitor according to the first embodiment of the present invention is mounted;

FIG. 8 is a perspective view showing an outer appearance of a capacitor and an outer appearance of a circuit board according to a second embodiment of the present invention;

FIG. 9 is a cross-sectional view showing the capacitor and the circuit board according to the second embodiment of the present invention as seen along a line C-C′ of FIG. 8; and

FIG. 10 is a graph showing an impedance frequency characteristic of the capacitor according to the first embodiment of the present invention, an impedance frequency characteristic of the capacitor according to the second embodiment of the present invention, and an impedance frequency characteristic of the conventional capacitor.

### DETAILED DESCRIPTION

Various embodiments according to the invention will be described hereinafter with reference to the accompanying drawings. In general, according to one embodiment of the invention, a capacitor includes a first anode terminal exposed from an end portion of a first inner electrode coupled to one side of a dielectric in a predetermined direction, a second anode terminal exposed from the other end portion of the first inner electrode in the predetermined direction, a first cathode terminal exposed from a predetermined portion of a second inner electrode that is connected to the other side of the dielectric and provided independently of the first inner electrode, to insides of the exposed portions of the first and second anode terminals, in the predetermined direction, and a second cathode terminal exposed from a part of the predetermined portion of the second inner electrode which is close to the second anode terminal, to the insides of the exposed portions of the first and second anode terminals, in the predetermined direction, at a predetermined interval from the first cathode terminal.

### First Embodiment

To make the characteristics of the present invention easily understood, a conventional capacitor is first explained.

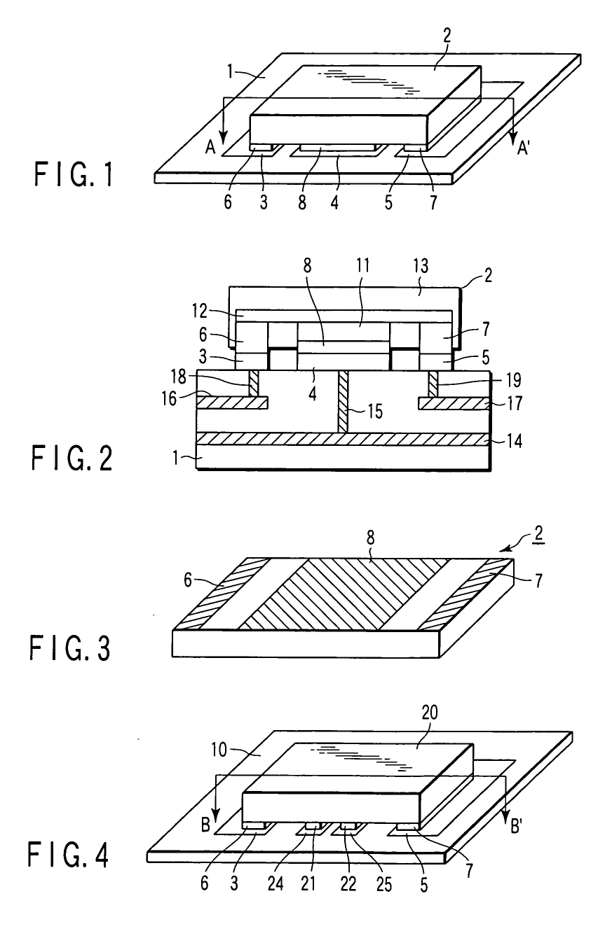

FIG. 1 is a perspective view showing outer appearance of a conventional capacitor and a conventional circuit board.

A conventional capacitor 2 is mounted on a circuit board 1 as shown in FIG. 1. The capacitor 2 is a polarized capacitor such as an aluminum electrolyte capacitor. Conductive pads 3, 4, 5 are provided on the circuit board 1. A first anode terminal 6, a second anode terminal 7, and a cathode terminal 8 are exposed from one of surface of the capacitor 2.

The pad 3 is bonded to the first anode terminal 6 of the capacitor 2 mounted on the circuit board 1. The pad 4 is bonded to the cathode terminal 8 of the capacitor 2 mounted on the circuit board 1. The pad 5 is bonded to the second anode terminal 7 of the capacitor 2 mounted on the circuit board 1.

FIG. 2 is a cross-sectional view showing the conventional capacitor 2 and the conventional circuit board 1 as seen along a line A-A′ of FIG. 1.

The capacitor 2 is formed by embedding a dielectric plate 11 and an internal electrode plate 12 in a mold 13 as shown in FIG. 2.

A part of a bottom surface of the internal electrode plate 12 is bonded to a top surface of the dielectric plate 11. An area of the internal electrode plate 12 is greater than an area of the dielectric plate 11. The top surface of the dielectric plate 11 is bonded to a substantially central part of the bottom surface of the internal electrode plate 12.

The first anode terminal 6 is bonded to one of end portions of the bottom surface of the internal electrode plate 12. End portions of the first anode terminal 6 are exposed from the mold 13 to the outside. The second anode terminal 7 is bonded to the other end portion of the bottom surface of the internal electrode plate 12. End portions of the second anode terminal 7 are exposed from the mold 13 to the outside. The direction of exposure of the first anode terminal 6 is the same as the direction of exposure of the second anode terminal 7.

The cathode terminal 8 is bonded to an entire area of a bottom surface of the dielectric plate 11. End portions of the cathode terminal 8 are exposed from the mold 13 to the outside. The exposed portion of the cathode terminal 8 is positioned inside the exposed portions of the first anode terminal 6 and the second anode terminal 7. The direction of exposure of the cathode terminal 8 is the same as the direction of exposure of the first anode terminal 6 and the second anode terminal 7.

In addition, a GND layer 14, a first VCC layer 16 and a second VCC layer 17 are provided inside the circuit board 1 as shown in FIG. 2. A GND through hole 15 is provided between the VDD layer 14 and the pad 4. A first VCC through hole 18 is provided between the first VCC layer 16 and the pad 3. A second VCC through hole 19 is provided between the second VCC layer 17 and the pad 5.

FIG. 3 is a perspective view showing an electrode exposure surface of the conventional capacitor. The first anode terminal 6, the second anode terminal 7 and the cathode terminal 8 are exposed from the capacitor 2 as shown in FIG. 3.

Next, a capacitor according to a first embodiment of the present invention is described.

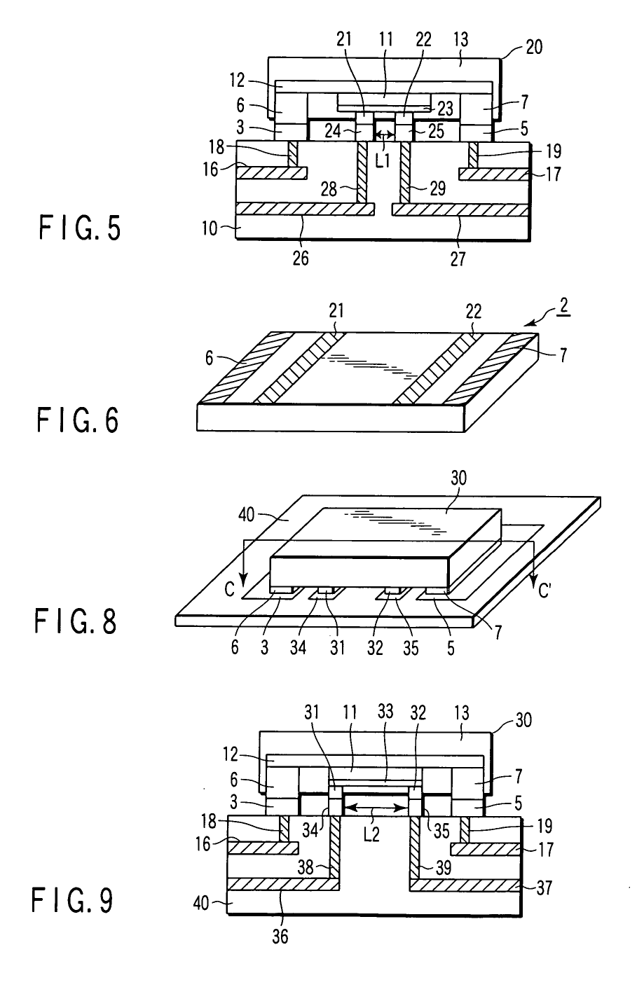

FIG. 4 is a perspective view showing an outer appearance of a capacitor 20 and an outer appearance of a circuit board 10 according to a first embodiment of the present invention. FIG. 5 is a cross-sectional view showing the capacitor and the circuit board according to the first embodiment of the present invention as seen along a line B-B′ of FIG. 4. Elements of the capacitor 20 and circuit board 10 like or similar to those of the capacitor 2 and the circuit board 1 are not described here.

The capacitor 20, as compared with the conventional capacitor 2, comprises a first cathode terminal 21 and a second cathode terminal 22 instead of the cathode terminal 8. A top surface of an inner electrode plate 23 is bonded to the bottom surface of the dielectric plate 11. The first cathode terminal 21 and the second cathode terminal 22 are connected with the inner electrode plate 23. Exposed portions of the first cathode terminal 21 and the second cathode terminal 22 are located inside the exposed portions of the first anode terminal 6 and the second anode terminal 7, respectively.

The circuit board 10 on which the capacitor is mounted comprises a pad 24 and a pad 25 instead of the pad 4 as compared with the circuit board 1 on which the conventional capacitor 2 is mounted. The pad 24 is bonded to the first cathode terminal 21 of the capacitor 20 mounted on the circuit board 10. The pad 25 is bonded to the second cathode terminal 22 of the capacitor 20 mounted on the circuit board 10.

As shown in FIG. 5, the capacitor 20 is formed by embedding the dielectric plate 11, the internal electrode plate 12 and the inner electrode plate 23 in the mold 13. A part of the bottom surface of the internal electrode plate 12 is bonded to the top surface of the dielectric plate 11. The area of the internal electrode plate 12 is greater than the area of the dielectric plate 11. The top surface of the dielectric plate 11 is bonded to a substantially central part of the bottom surface of the internal electrode plate 12.

The first anode terminal 6 is bonded to one of end portions of the bottom surface of the internal electrode plate 12 of the capacitor 20, similarly to the capacitor 2 shown in FIG. 1. The end portions of the first anode terminal 6 are exposed from the mold 13 to the outside. The second anode terminal 7 is bonded to the other end portion of the bottom surface of the internal electrode plate 12. The end portions of the second anode terminal 7 are exposed from the mold 13 to the outside. The direction of exposure of the first anode terminal 6 is the same as the direction of exposure of the second anode terminal 7.

The first cathode terminal 21 is bonded between a center of a bottom surface of the inner electrode plate 23 and the end portion of the dielectric plate 11 which is close to the first anode terminal 6. End portions of the first cathode terminal 21 are exposed from the mold 13 to the outside. The second cathode terminal 22 is bonded between the center of the bottom surface of the inner electrode plate 23 and the end portion of the dielectric plate 11 which is close to the second anode terminal 7. End portions of the second cathode terminal 22 are exposed from the mold 13 to the outside.

The direction of exposure of the first cathode terminal 21 and the second cathode terminal 22 is the same as the first anode terminal 6 and the second anode terminal 7. The first cathode terminal 21 and the second cathode terminal 22 may be formed of different substances if they are conductive.

There is a distance having a length L1 between the pad 24 and the pad 25 and between the first cathode terminal 21 and the second cathode terminal 22.

In addition, a first GND layer 26 and a second GND layer 27 are provided instead of the GND layer 14, in the circuit board 10, as shown in FIG. 5. The first GND layer 26 and the second GND layer 27 are provided independently.

In the circuit board 10, too, a first GND through hole 28 is provided between the first GND layer 26 and the pad 24, instead of the single GND through hole 15. A second GND through hole 29 is provided between the second GND layer 27 and the pad 25.

In the capacitor 20, the distance between the first anode terminal 6 and the first cathode terminal 21 is equal to the distance between the second cathode terminal 22 and the second anode terminal 7. In the circuit board 10, the distance between the pads 3 and 24 is equal to the distance between the 25 and 5.

FIG. 6 is a perspective view showing an electrode exposure surface of the capacitor according to the first embodiment of the present invention. The first anode terminal 6, the second anode terminal 7, the first cathode terminal 21 and the second cathode terminal 22 are exposed from the capacitor 20 as shown in FIG. 6. The area of the exposed portions of the cathode terminals is smaller on the electrode exposure surface than that on the electrode exposure surface of the circuit board 1 shown in FIG. 3.

In the capacitor 20 according to the first embodiment of the present invention, as described above, the exposed portions of the cathode terminals are partially closed as compared with the conventional capacitor 2. Thus, when the capacitor 20 is mounted on the circuit board 10, other wiring patterns can be formed on the circuit board 10 opposite to the closed part or other through holes can be provided from the closed part into the circuit board 10.

Plural cathode terminals are exposed to the outside of the capacitor 20. The impedance characteristic in the high-frequency band in a case where the capacitor is mounted on the circuit board in which the GND layer and the GND through hole are formed for each cathode terminal, is improved as compared with the impedance characteristic in the high-frequency band in a case where the capacitor having one exposed cathode terminal is mounted on the circuit board.

As an example of mounting the capacitor 20, the second VCC layer 17 and the second GND layer 27 of the circuit board 10 are connected to the power supply and the first VCC layer 16 and the first GND layer 26 are connected to an electronic component operated with the high frequency of the CPU, etc.

In this case, the second VCC layer 17, the second VCC through hole 19, the pad 5, the second anode terminal 7, the internal electrode plate 12, the first anode terminal 6, the pad 3, the first VCC through hole 18 and the first VCC layer 16 are a part of a power supply line making a connection between the positive terminal of the power supply and the electronic component. In addition, the first GND layer 26, the first GND through hole 28, the pad 24, the first cathode terminal 21, the inner electrode plate 23, the second cathode terminal 22, the pad 25, the second GND through hole 29 and the second GND layer 27 are a part of a power supply line making a connection between the electronic component and the negative terminal of the power supply.

The impedance characteristic in the high-frequency band is improved since influence of the inductance to the terminal portions is reduced as compared with a conventional case where the capacitor is connected between the power supply lines.

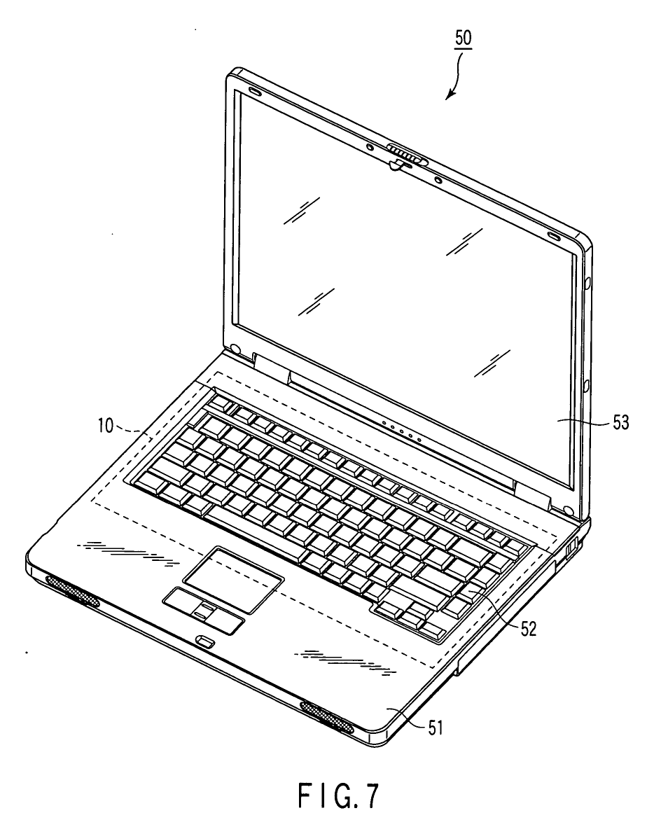

The circuit board 10 is contained in an electronic apparatus such as a notebook-type PC. FIG. 7 is a perspective view showing an outer appearance of a notebook-type PC 50 containing a circuit board 10 on which a capacitor 20 according to the first embodiment of the present invention is mounted.

The notebook-type PC 50 comprises a housing 51, a keyboard 52 and a display 53 as shown in FIG. 7. The housing 51 contains the circuit board 10.

In the capacitor 20, the distance between the first anode terminal 6 and the first cathode terminal 21 is equal to the distance between the second cathode terminal 22 and the second GND layer 27. Therefore, the impedance characteristic in the high-frequency band in a case where the capacitor is mounted on the circuit board in which the GND layer and the GND through hole are provided for each cathode terminal is improved as compared with the impedance characteristic in the above-explained case where the distance between the anode terminal and the cathode terminal is irregular.

### Second Embodiment

Next, A second embodiment of the present invention will be described. FIG. 8 is a perspective view showing an outer appearance of a capacitor 30 and an outer appearance of a circuit board 40 according to the second embodiment of the present invention. FIG. 9 is a cross-sectional view showing the capacitor 30 and the circuit board 40 according to the second embodiment of the present invention as seen along a line C-C′ of FIG. 8. Elements of the capacitor 30 and circuit board 40 like or similar to those of the capacitor 20 and the circuit board 10 employed in the first embodiment are not described here.

The capacitor 30 comprises a first cathode terminal 31 and a second cathode terminal 32 instead of the first cathode terminal 21 and the second cathode terminal 22, respectively, as compared with the capacitor 20 employed in the first embodiment. A top surface of an inner electrode plate 33 is bonded to the bottom surface of the dielectric plate 11. The first cathode terminal 31 and the second cathode terminal 32 are connected with the inner electrode plate 33.

The circuit board 40 on which the capacitor 30 is mounted comprises a pad 34 and a pad 35 instead of the pads 24, 25 as compared with the circuit board 10 employed in the first embodiment.

The pad 34 is bonded to the first cathode terminal 31 of the capacitor 30 mounted on the circuit board 40. The pad 35 is bonded to the second cathode terminal 32 of the capacitor 30 mounted on the circuit board 40.

As shown in FIG. 9, the capacitor 30 is formed by embedding the dielectric plate 11, the internal electrode plate 12 and the inner electrode plate 33 in the mold 13. The first cathode terminal 31 is bonded to an end portion of the bottom surface of the inner electrode plate 33 which is close to the first anode terminal 6. End portions of the first cathode terminal 31 are exposed from the mold 13 to the outside. The second cathode terminal 32 is bonded to an end portion of the bottom surface of the inner electrode plate 33 which is close to the second anode terminal 7. End portions of the second cathode terminal 32 are exposed from the mold 13 to the outside.

The direction of exposure of the first cathode terminal 31 and the second cathode terminal 32 is the same as the first anode terminal 6 and the second anode terminal 7. The first cathode terminal 31 and the second cathode terminal 32 may be formed of different substances if they are conductive.

There is a distance having a length L2 between the pad 34 and the pad 35 and between the first cathode terminal 31 and the second cathode terminal 32. The length L2 is greater than the length L1 of the first embodiment.

In addition, in the circuit board 40 as shown in FIG. 9, a first GND layer 36 and a second GND layer 37 are provided instead of the first GND layer 26 and the second GND layer 27 of the first embodiment.

In the circuit board 40, too, a first GND through hole 38 is provided between the first GND layer 36 and the pad 34, instead of the first GND through hole 28 and the second GND through hole 29. A second GND through hole 39 is provided between the second GND layer 37 and the pad 35.

In the capacitor 30, the distance between the first anode terminal 6 and the first cathode terminal 31 is equal to the distance between the second cathode terminal 32 and the second anode terminal 7. In the circuit board 40, the distance between the pads 3 and 34 is equal to the distance between the pads 35 and 5.

In the capacitor 30 according to the second embodiment of the present invention, as described above, the distance between the exposed portions of the cathode terminal is longer than that in the capacitor 20 of the first embodiment. The impedance characteristic in the high-frequency band obtained by mounting this capacitor on a circuit board on which the GND layer and the GND through hole are provided for each cathode terminal, is improved as compared with the impedance characteristic of the capacitor 20 according to the first embodiment.

In addition, the impedance characteristic in the high-frequency band obtained by mounting this capacitor on a circuit board on which the GND layer and the GND through hole are provided for each cathode terminal, in a case where in the capacitor 30, the distance between the first anode terminal 6 and the first cathode terminal 31 is equal to the distance between the second cathode terminal 32 and the second anode terminal 7, is improved as compared with a case where the distance is irregular.

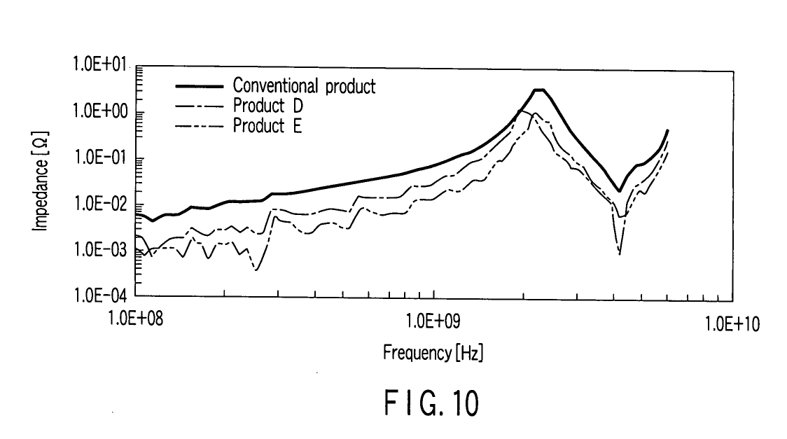

FIG. 10 is a graph showing an impedance frequency characteristic of the capacitor according to the first embodiment of the present invention, an impedance frequency characteristic of the capacitor according to the second embodiment of the present invention, and an impedance frequency characteristic of the conventional capacitor.

“Product D” shown in FIG. 10 represents a product in which the capacitor 20 according to the first embodiment is built. “Product E” shown in FIG. 10 represents a product in which the capacitor 30 according to the second embodiment is built. “Conventional Product” shown in FIG. 10 represents a product in which the capacitor 2 is built.

As shown in FIG. 10, the impedance of each frequency of the product in which the capacitor 20 according to the first embodiment is built is generally low as compared with the impedance of each frequency of the product in which the conventional capacitor 2 is built. In addition, the impedance of each frequency of the product in which the capacitor 30 according to the second embodiment is built is generally low as compared with the impedance of each frequency of the product in which the capacitor 20 according to the first embodiment is built.

In other words, a operating voltage of the apparatus correctly follows the variation in the power supply voltage of the apparatus in a case where the capacitors according to the first and second embodiments are employed together with an electronic component such as a CPU of a personal computer which is operated with a high frequency. Therefore, since the power supply voltage of the apparatus becomes stable as compared with a case of employing the conventional capacitor 2, the stability of the operations can be improved.

In the above-described embodiments, two cathode terminals are exposed from the mold 13 to the outside but, for example, three cathode terminals may be exposed from the mold 13 to the outside. In this case, the VCC layers, the GND layers and various kinds of through holes whose number correspond to the number of cathode terminals may be provided on the circuit board side on which the capacitor is mounted.

In the above-described embodiments, too, the dielectric plate is sandwiched between the anode electrode and the cathode electrode but, for example, a rod-shaped electrode for anode may be wrapped with a dielectric layer and the dielectric layer may be wrapped with an electrode layer for cathode. In this case, anode terminals are provided at both end portions of the rod-shaped electrode for anode, respectively, and exposed to the outside, and a plurality of cathode terminals are attached to the electrode layer for cathode and exposed to the outside.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A capacitor, comprising:
a first anode terminal exposed from an end portion of a first inner electrode coupled to one side of a dielectric in a predetermined direction;
a second anode terminal exposed from the other end portion of the first inner electrode in the predetermined direction;
a first cathode terminal exposed from a predetermined portion of a second inner electrode that is connected to the other side of the dielectric and provided independently of the first inner electrode, to insides of the exposed portions of the first and second anode terminals, in the predetermined direction; and
a second cathode terminal exposed from a part of the predetermined portion of the second inner electrode which is close to the second anode terminal, to the insides of the exposed portions of the first and second anode terminals, in the predetermined direction, at a predetermined interval from the first cathode terminal.

2. The capacitor according to claim 1, wherein the first cathode terminal is exposed from an end portion of the second inner electrode which is close to the first anode terminal; and
the second cathode terminal is exposed from an end portion of the second inner electrode which is close to the second anode terminal.

3. The capacitor according to claim 1, wherein a distance between the first anode terminal and the first cathode terminal is equal to a distance between the second anode terminal and the second cathode terminal.

4. An electronic apparatus, comprising a circuit board on which a capacitor is mounted, the capacitor comprising:
a first anode terminal exposed from an end portion of a first inner electrode coupled to one side of a dielectric in a predetermined direction;
a second anode terminal exposed from the other end portion of the first inner electrode in the predetermined direction;
a first cathode terminal exposed from a predetermined portion of a second inner electrode that is connected to the other side of the dielectric and provided independently of the first inner electrode, to insides of the exposed portions of the first and second anode terminals, in the predetermined direction; and
a second cathode terminal exposed from a part of the predetermined portion of the second inner electrode which is close to the second anode terminal, to the insides of the exposed portions of the first and second anode terminals, in the predetermined direction, at a predetermined interval from the first cathode terminal.

5. The electronic apparatus according to claim 4, wherein in the capacitor, the first cathode terminal the is exposed from an end portion of the second inner electrode which is close to the first anode terminal, and the second cathode terminal is exposed from an end portion of the second inner electrode which is close to the second anode terminal.

6. The capacitor according to claim 4, wherein in the capacitor, a distance between the first anode terminal and the first cathode terminal is equal to a distance between the second anode terminal and the second cathode terminal.
